(19) United States
(12) Patent Application Publication
(10) Pub. No.: US 2025/0165186 A1
(43) Pub. Date: May 22, 2025

(54) MEMORY DEVICES, CONTROL METHODS THEREOF, AND MEMORY SYSTEMS

(71) Applicant: YANGTZE MEMORY TECHNOLOGIES CO., LTD., Wuhan (CN)

(72) Inventors: Wang HE, Wuhan (CN); Xiaodong MEI, Wuhan (CN); HuangPeng ZHANG, Wuhan (CN); Debo WEI, Wuhan (CN)

(21) Appl. No.: 18/679,955

(22) Filed: May 31, 2024

(30) Foreign Application Priority Data
Nov. 22, 2023 (CN) 202311574212.6

(51) Int. Cl. G06F 3/06

(52) U.S. Cl. CPC G06F 3/0659; G06F 3/061; G06F 3/0679

(57) ABSTRACT

Examples of the present disclosure include a memory device, a control method thereof, and a memory system. The memory device includes a memory array and a peripheral circuit coupled to the memory array. The memory array includes memory rows each including memory cells coupled to one word line. The peripheral circuit is configured to determine, in response to a read command, whether address information same as first address information of a first memory row corresponding to the read command exists in a refresh table. The refresh table stores pieces of address information each corresponding to one of the memory rows. The peripheral circuit is configured to delete the address information same as the first address information from the refresh table in response to the address information same as the first address information existing in the refresh table.

### CROSS-REFERENCE TO RELATED APPLICATIONS

The present application claims the benefit of priority to China Application No. 202311574212.6, filed on Nov. 22, 2023, the content of which is incorporated herein by reference in its entirety.

### TECHNICAL FIELD

Examples of the present disclosure relate to the field of semiconductor technology, for example, to memory devices, methods of controlling memory device, and memory systems.

### BACKGROUND

A memory device is a storage device used to save information in modern information technique, for example, a dynamic random access memory (DRAM), and may comprise a memory array and a peripheral circuit. The peripheral circuit may be configured to control the memory array, to operate the memory array to perform read, write or refresh operations.

### SUMMARY

According to some aspects of examples of the present disclosure, a memory device is provided. The memory device may include a memory array and a peripheral circuit. The memory array includes memory rows each comprising memory cells coupled to one word line. The peripheral circuit is coupled to the memory array and configured to determine, in response to a read command, whether address information same as first address information of a first memory row corresponding to the read command exists in a refresh table. The refresh table stores pieces of address information, and each of the pieces of address information corresponds to one of the memory rows. The peripheral circuit is further configured to delete the address information same as the first address information from the refresh table in response to the address information same as the first address information existing in the refresh table.

In some examples, the pieces of address information are sorted by priority. The peripheral circuit is further configured to perform a refresh operation on a corresponding memory row according to address information with the highest priority in the refresh table, and delete the address information with the highest priority from the refresh table after the refresh operation.

In some examples, the peripheral circuit is further configured to determine whether address information of a memory row adjacent to the first memory row exists in the refresh table; insert the address information of the memory row adjacent to the first memory row into the refresh table in response to the address information of the memory row adjacent to the first memory row not existing in the refresh table; and adjust priority of the address information of the memory row adjacent to the first memory row in the refresh table in response to the address information of the memory row adjacent to the first memory row existing in the refresh table.

In some examples, the refresh table includes a first sub-table and a second sub-table, and priority of address information in the first sub-table is higher than priority of address information in the second sub-table.

In some examples, the peripheral circuit is further configured to insert the address information of the memory row adjacent to the first memory row into the second sub-table in response to the address information of the memory row adjacent to the first memory row not existing in the refresh table. Priority of the address information of the memory row adjacent to the first memory row is the highest priority in the second sub-table.

In some examples, the memory row adjacent to the first memory row includes a second memory row and a third memory row. The peripheral circuit is further configured to insert second address information corresponding to the second memory row and third address information corresponding to the third memory row into the second sub-table in response to address information same as the second address information and address information same as the third address information not existing in the refresh table. Priority of the second address information is the highest priority in the second sub-table, and priority of the third address information is the second highest priority in the second sub-table. Or, priority of the second address information is the second highest priority in the second sub-table, and priority of the third address information is the highest priority in the second sub-table.

In some examples, the peripheral circuit is further configured to adjust priority of the address information of the memory row adjacent to the first memory row to the highest priority in the first sub-table in response to the address information of the memory row adjacent to the first memory row existing in the first sub-table.

In some examples, the peripheral circuit is further configured to move the address information of the memory row adjacent to the first memory row into the first sub-table in response to the address information of the memory row adjacent to the first memory row existing in the second sub-table.

In some examples, priority of the address information of the memory row adjacent to the first memory row is the lowest priority in the first sub-table.

In some examples, the peripheral circuit is further configured to delete at least one piece of address information in the second sub-table when the number of pieces of address information stored in the second sub-table is greater than a set threshold.

In some examples, the peripheral circuit is configured to delete address information in the second sub-table in order of priority. Address information with a lower priority is to be deleted earlier.

In some examples, the peripheral circuit is further configured to, in response to the address information with the highest priority being deleted from the refresh table after the refresh operation, raise all priority corresponding to remaining address information in the refresh table by one level and insert fourth address information corresponding to a fourth memory row into the refresh table. Priority of the fourth address information is the lowest priority in the refresh table.

In some examples, priority of each piece of address information of the plurality of pieces of address information is determined according to a probability that a memory row corresponding to the address information suffers a row-hammer attack.

In some examples, the peripheral circuit may include a control logic and a comparison circuit coupled to the control logic. The comparison circuit is configured to, in response to the read command, acquire individual pieces of address information in the refresh table, and compare the first address information with the individual pieces of address information one by one to generate a comparison result. The comparison circuit is further configured to send the comparison result to the control logic. The control logic is configured to determine, according to the comparison result, whether the address information same as the first address information exists in the refresh table. The control logic is further configured to delete the first address information from the refresh table in response to the address information same as the first address information existing in the refresh table.

According to some aspects of examples of the present disclosure, a memory system is provided. The memory system may include the memory device in the above examples; and a memory controller coupled to the memory device and configured to control the memory device.

According to some aspects of examples of the present disclosure, a method of controlling a memory device is provided. The method may include determining, in response to a read command, whether address information same as first address information of a first memory row corresponding to the read command exists in a refresh table. The refresh table stores pieces of address information each corresponding to one of memory rows. Each of the memory rows includes memory cells coupled to one word line. The method further includes deleting the address information same as the first address information from the refresh table in response to the address information same as the first address information existing in the refresh table.

In some examples, the plurality of pieces of address information are sorted by priority. The method further includes performing a refresh operation on a corresponding memory row according to address information with the highest priority in the refresh table, and deleting the address information with the highest priority from the refresh table after the refresh operation.

In some examples, the method further includes determining whether address information of a memory row adjacent to the first memory row exists in the refresh table; inserting the address information of the memory row adjacent to the first memory row into the refresh table in response to the address information of the memory row adjacent to the first memory row not existing in the refresh table; and adjusting priority of the address information of the memory row adjacent to the first memory row in the refresh table in response to the address information of the memory row adjacent to the first memory row existing in the refresh table.

In some examples, the refresh table includes a first sub-table and a second sub-table, and priority of address information in the first sub-table is higher than priority of address information in the second sub-table.

In some examples, the method may include inserting the address information of the memory row adjacent to the first memory row into the second sub-table in response to the address information of the memory row adjacent to the first memory row not existing in the refresh table Priority of the address information of the memory row adjacent to the first memory row is the highest priority in the second sub-table.

In some examples, the memory row adjacent to the first memory row includes a second memory row and a third memory row The method includes inserting second address information corresponding to the second memory row and third address information corresponding to the third memory row into the second sub-table in response to address information same as the second address information and address information same as the third address information not existing in the refresh table. Priority of the second address information is the highest priority in the second sub-table, and priority of the third address information is the second highest priority in the second sub-table. Or, priority of the second address information is the second highest priority in the second sub-table, and priority of the third address information is the highest priority in the second sub-table.

In some examples, the method includes adjusting priority of the address information of the memory row adjacent to the first memory row to the highest priority in the first sub-table in response to the address information of the memory row adjacent to the first memory row existing in the first sub-table.

In some examples, the method includes moving the address information of the memory row adjacent to the first memory row into the first sub-table in response to the address information of the memory row adjacent to the first memory row existing in the second sub-table.

In some examples, priority of the address information of the memory row adjacent to the first memory row is the lowest priority in the first sub-table.

In some examples, the method further includes deleting at least one piece of address information in the second sub-table, when the number of pieces of address information stored in the second sub-table is greater than a set threshold.

In some examples, the method includes deleting address information in the second sub-table in order of priority. Address information with a lower priority is to be deleted earlier.

In some examples, the method includes raising all priority corresponding to remaining address information in the refresh table by one level in response to the address information with the highest priority being deleted from the refresh table after the refresh operation; and inserting fourth address information corresponding to a fourth memory row into the refresh table. Priority of the fourth address information is the lowest priority in the refresh table.

In some examples, priority of each piece of address information of the pieces of address information is determined according to a probability that a memory row corresponding to the address information suffers a row-hammer attack.

### BRIEF DESCRIPTION OF THE DRAWINGS

FIG. 1 is a schematic diagram of a system comprising a memory system according to examples of the present disclosure;

FIG. 2 is a schematic diagram of a system comprising a memory device according to examples of the present disclosure;

FIG. 3 is a schematic diagram of a memory array and a peripheral circuit according to examples of the present disclosure;

FIG. 4 is a schematic diagram of a memory device comprising a peripheral circuit according to examples of the present disclosure;

FIG. 5 to FIG. 10 are schematic diagrams of operations on a refresh table according to examples of the present disclosure; and

FIG. 11 is a schematic flow diagram of a method of controlling a memory device according to examples of the present disclosure.

In the above drawings (which not necessarily drawn to scale), like reference numerals may describe like components in different views. Like reference numerals having different letter suffixes may represent different examples of like components. The accompanying drawings illustrate generally, by way of example, but not by way of limitation, various examples as discussed herein.

### DETAILED DESCRIPTION

Examples disclosed in the present disclosure will be described in more detail below with reference to the accompanying drawings. Although examples of the present disclosure are shown in the drawings, it should be understood that the present disclosure may be implemented in various ways and should not be limited to the DETAILED DESCRIPTION set forth herein. Rather, these examples are provided so that the present disclosure can be more thoroughly understood and the scope disclosed in the present disclosure can be fully conveyed to those skilled in the art.

In the following description, numerous specific details are given in order to provide a more thorough understanding of the present disclosure. It will be apparent, however, to one skilled in the art that the present disclosure may be practiced without one or more of these details. In other examples, some technical features well-known in the art are not described to avoid confusion with the present disclosure; that is, not all features of the actual example are described here, and well-known functions and structures are not described in detail.

In the accompanying drawings, like reference numerals refer to like elements throughout.

It should be understood that, spatial relationship terms such as “under”, “below”, “beneath”, “underneath”, “on”, “above” and so on, can be used here for convenience to describe the relationship between one element or feature and other elements or features shown in the figures. It will be understood that the spatially relationship terms also comprise or include different orientations of the device in use and operation in addition to the orientation depicted in the figures. For example, if the device in the figures is turned over, elements or features described as “below” or “underneath” or “under” other elements or features would then be oriented as “above” the other elements or features. Thus, the example terms “below” and “under” can comprise both orientations of above and below. The device may be otherwise oriented (rotated 90 degrees or at other orientations) and the spatial terms used herein may be interpreted accordingly.

The terminology used herein is for the purpose of describing particular examples only and is not to be taken as a limitation of the present disclosure. As used herein, “a”, “an” and “said/the” in singular forms are intended to include the plural forms as well, unless the context clearly dictates otherwise. It should also be understood that at least one of the terms “consists of”, “including” or “comprising”, when used in this specification, identify the presence of at least one of stated features, integers, operations, elements or components, but do not exclude presence or addition of at least one of one or more other features, integers, operations, elements, components or groups. As used herein, the term “at least one of . . . ” includes any and all combinations of the associated listed items.

It is to be understood that, references to “some examples” or “an example” throughout this specification mean that particular features, structures, or characteristics related to the example are comprised or included in at least one example of the present disclosure. Therefore, “in some examples” or “in an example” presented everywhere throughout this specification does not necessarily refer to the same example. Furthermore, these particular features, structures, or characteristics may be incorporated in one or more examples in any suitable manner. It is to be understood that, in various examples of the present disclosure, sequence numbers of the above processes do not indicate an execution sequence, and the execution sequence of various processes shall be determined by functionalities and intrinsic logics thereof, and shall constitute no limitation on an implementation process of the examples of the present disclosure. The above sequence numbers of the examples of the present disclosure are only for description, and do not represent advantages or disadvantages of the examples.

The methods disclosed in several method examples as provided by examples of the present disclosure may be combined freely to obtain new method examples in case of no conflicts. A memory device in the examples of the present disclosure may be a DRAM, or at least some devices of a DRAM, and is applicable for a double data rate synchronous dynamic random access memory using DDR4 memory specifications and DDR5 memory specifications and a low power consumption double data rate synchronous dynamic random access memory using LPDDR5 memory specifications. It is to be noted that the examples of the present disclosure are not limited to a DRAM. However, in subsequent introduction, for clear description, a DRAM is only used as an example for description.

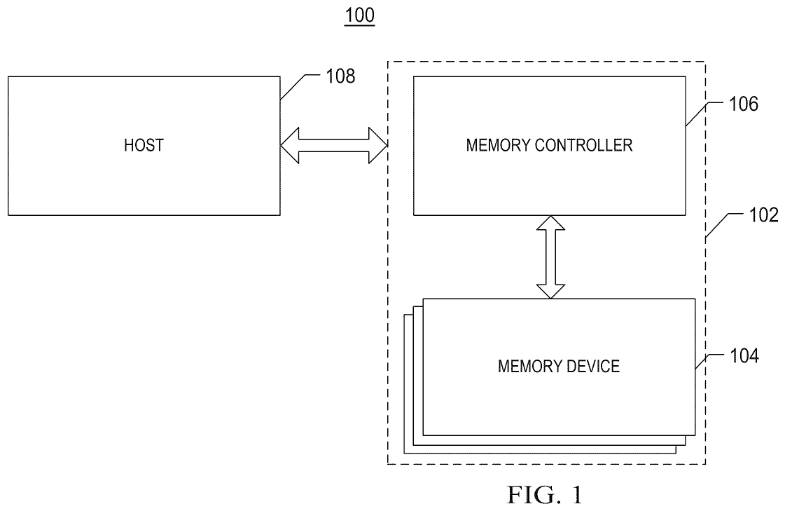

With reference to FIG. 1, examples of the present disclosure provide a system 100 including a host 108. The system 100 may be a mobile phone, a desktop computer, a laptop computer, a tablet computer, a vehicle computer, a gaming console, a printer, a positioning device, a wearable electronic device, a smart sensor, a virtual reality (VR) device, an augmented reality (AR) device, or any other suitable electronic devices having storage therein. As shown in FIG. 1, the system 100 may include a host 108 and a memory system 102. The memory system 102 has one or more memory devices 104 and a memory controller 106. The host 108 may be a processor (e.g., a central processing unit (CPU)) or a system on chip (SOC) (e.g., an application processor (AP)) of an electronic device. The host 108 may be configured to send or receive data to or from the memory device 104.

According to some examples, the memory controller 106 is coupled to the memory device 104 and the host 108 and is configured to control the memory device 104, to perform read, write or refresh operations. The memory controller 106 can manage the data stored in the memory device 104 and communicate with the host 108. The memory device 104 includes a DRAM, or a package structure formed by stacking a plurality of DRAMs, for example, an HBM or HMC package structure. The memory system 102 may serve as a memory of the host 108 in the system 100 or a buffer of the system 100. In some examples, the memory system 102 may be for auxiliary use in a solid-state drive, which can make improvements on the solid-state drive in terms of reading and writing. Current high-end solid-state drive products mostly select embedded DRAMs to improve the performance of the products, and improve the random reading-writing speeds. In an example, when writing files, especially writing small files, the small files are stored in a Flash after being processed by the DRAMs, such that the solid-state drive has higher storage efficiency and faster speed. The Flash includes a non-volatile memory, and includes, but is not limited to, a 2D NAND memory or a 3D NAND memory.

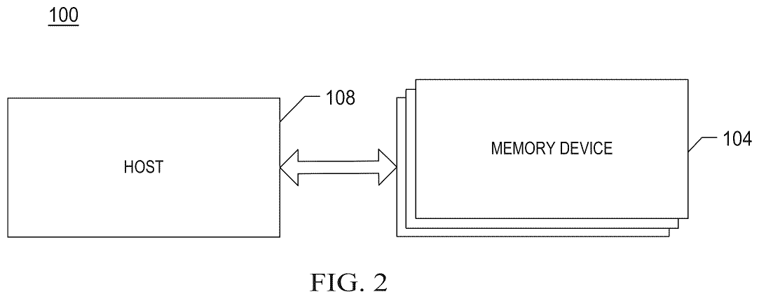

In some other examples, with reference to FIG. 2, the system 100 may include only the host 108 and the memory device 104 coupled to the host. A controller that controls the memory device 104 may be located inside the host 108, for example, a memory controller may be integrated in a central processing unit (CPU), or a southbridge or northbridge chip may be integrated in a mainboard of the system 100. The memory device 104 may include, but is not limited to, a double data rate synchronous dynamic random access memory using DDR4 memory specifications and DDR5 memory specifications and a low power consumption double data rate synchronous dynamic random access memory using LPDDR5 memory specifications.

In some examples provided by the present disclosure, it should be understood that the disclosed device and method may be implemented in a manner different from the subject. The device examples as described above are only illustrative, for example, the division of the units is only a logical functional division. In an actual example, there may be another manner for division. For instance, a plurality of units or components may be combined, or may be integrated in another system, or some features can be ignored or not performed. In addition, the various constituent parts as shown or as discussed may be directly or indirectly coupled to each other.

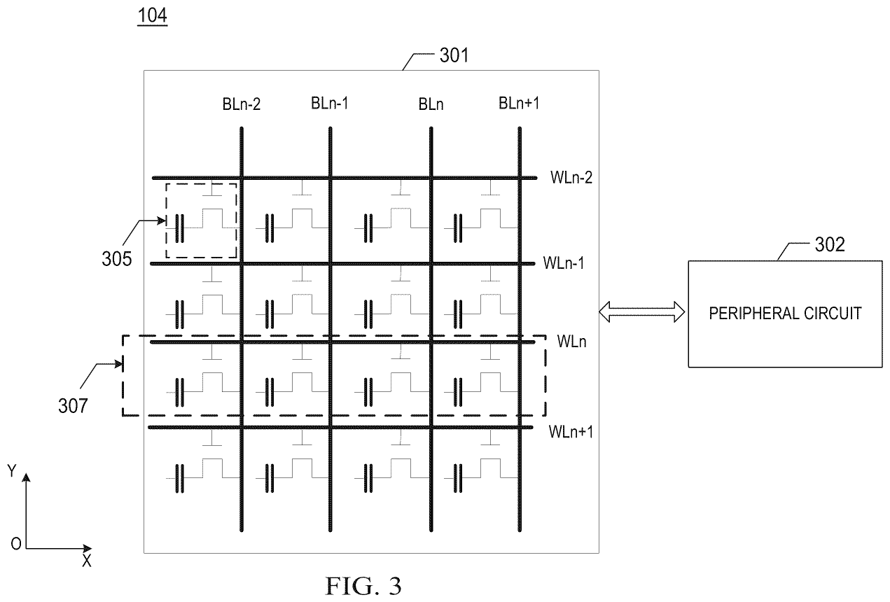

FIG. 3 is a schematic diagram of a memory array 301 and a peripheral circuit 302 according to examples of the present disclosure. As shown in FIG. 3, in a DRAM, the memory array 301 may be arranged in rows and columns, such that a memory cell 305 may be addressed by specifying a row and a column of an array to which the memory cell belongs. The peripheral circuit 302 is coupled to the memory array 301 and configured to control the read, write or refresh operations of the memory array 301. The memory array 301 includes a plurality of word lines, for example, WLn, WLn+1, WLn−1, and WLn−2 shown in FIG. 3. The memory array 301 further includes a plurality of bit lines, for example, BLn, BLn+1, BLn−1, and BLn−2 shown in FIG. 3. The word lines and the bit lines intersect, and the memory cell 305 at an intersection of a selected word line and a selected bit line is a selected memory cell on which the read, write or refresh operation is to be performed. A plurality of memory cells 305 coupled to one word line form one memory row. One memory cell 305 shown in FIG. 3 may include a capacitor and a transistor, and one memory cell 305 may include one transistor and one capacitor. A gate of the transistor is coupled to a word line, one controlled terminal (source) of the transistor is coupled to one electrode (first electrode) of the capacitor, the other controlled terminal (source) of the transistor is coupled to a bit line, and the other electrode (second electrode) of the capacitor may be grounded or applied with another voltage (for example, vdd/2). As shown in FIG. 3, the memory array 301 is arranged in an array of x rows and y columns. The rows and the columns may be perpendicular or not perpendicular. An extension direction of the word lines may be parallel to an x direction or have an angle with the x direction. An extension direction of the bit lines may be parallel to a y direction or have an angle with the y direction. Orthographic projections of the word lines onto an xoy plane and orthographic projections of the bit lines onto the xoy plane are perpendicular, or are not perpendicular but have a certain angle with each other. This is not limited in the examples of the present disclosure. During a read or write operation, a corresponding word line may be selected by using a word line selection signal, and a corresponding bit line may be selected according to a column selection signal. When both a word line and a bit line are selected, a memory cell 305 may be selected, on which read and write operations are to be performed. In some examples, the capacitor in FIG. 3 may be replaced with another memory structure, which includes, but is not limited to, a phase change memory structure, a resistive memory structure or a magnetic memory structure, etc.

In some examples, the capacitor represents logic 1 and 0 according to the amount of charges stored in the capacitor or a voltage difference between two terminals of the capacitor. A voltage signal on a word line is applied to the gate to control the turn-on or turn-off of the transistor, enabling the selection on the capacitor, so as to read data information stored in the capacitor through a bit line, or write data to the capacitor through a bit line for storage. During reading of the memory cell 305, a sense amplifier (SA) circuit in the peripheral circuit 302 is coupled to a bit line. The sense amplifier circuit is configured to capture a weak voltage fluctuation on the bit line, and restore a voltage of the capacitor of the memory cell 305 is locally according to the voltage fluctuation. The sense amplifier circuit may include a latch, which may latch a value of the restored voltage of the capacitor, such that information stored in the memory cell 305 is transferred from the capacitor to the sense amplifier circuit. The sense amplifier circuit may include a differential sense amplifier circuit. The differential sense amplifier circuit is coupled to two bit lines, in which one selected bit line and a complementary bit line used as a reference line are used for operation, to detect and amplify a voltage difference on one pair of bit lines.

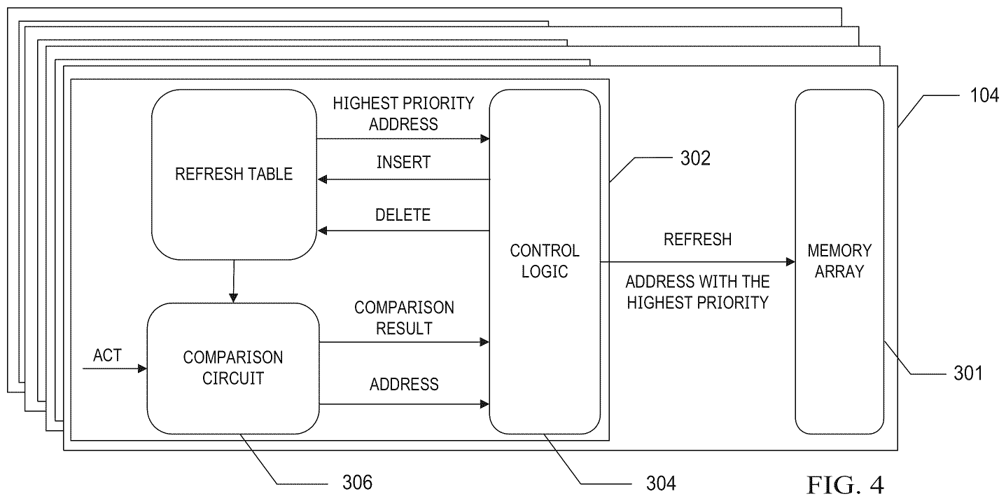

The peripheral circuit 302 may further include other devices such as a control logic (a control logic 304 shown in FIG. 4), a row decoding circuit, a column decoding circuit, a voltage generator, etc. The control logic 304 is configured to exchange signals with the host 108, a storage controller or a memory controller 106. The control logic 304 is configured to control devices such as the row decoding circuit (a row decoder), the column decoding circuit (a column decoder), the voltage generator, etc. in the peripheral circuit 302, to perform read, write or refresh operations on the memory cell 305 in the memory array 301. The row decoding circuit is coupled to the word lines, and is configured to perform row address decoding or row addressing, and apply a corresponding operation voltage to a word line on which an operation needs to be performed. The column decoding circuit is coupled to the bit lines, and is configured to perform column address decoding or column addressing.

In an example, when receiving an access request of the host 108 or the memory controller 106, the memory device 104 receives an address signal, and perform a read, write or refresh operation on a memory cell 305 corresponding to the address signal. The address signal may include a row address signal and a column address signal. The peripheral circuit 302 performs an address decoding or addressing operation. The row address signal may be inputted into a row address buffer, and decoded by the row decoding circuit to output a row selection signal. The row selection signal indicates to activate a word line in which a memory cell 305 on which an operation needs to be performed is located. The column address signal is inputted into a column address buffer, and decoded by the column decoding circuit to output a column selection signal. The column selection signal indicates to activate a bit line in which a memory cell 305 on which an operation needs to be performed is located. A memory cell 305 at an intersection of the activated bit line and the activated word line, or for example, a memory cell 305 coupled to both the activated bit line and the activated word line is a memory cell 305 on which an operation needs to be performed.

For a DRAM, there is a security vulnerability of a row-hammer attack. That is, when the number of times that memory cells 305 on a certain memory row in the memory array 301 are accessed is large, for example, when the read operations are performed on the memory row (for example, a first memory row 307) millions of times per second, charges in memory cells 305 in the accessed (for example, hammerer) memory row are leaked to memory cells 305 in an adjacent memory row, and as a result, the memory cells 305 in the adjacent the memory row is bit-flipped, leading to a data error. A memory row that suffers a row-hammer attack and is accessed is an attacked row, and a memory row adjacent to the memory row is a victim row. As the storage density of the memory array 301 keeps increasing, spacing between adjacent memory rows becomes increasingly smaller, and spacing between word lines becomes increasingly smaller, the risk of mutual interference between adjacent memory rows as well as the risk of charge leakage becomes increasingly higher, and the risk of data flipping on the memory rows due to a row-hammer attack also becomes increasingly higher.

In some examples of the present disclosure, capacitors that store data in a DRAM are inherently subject to charge leakage, and the memory cells 305 are generally refreshed periodically, to maintain an amount of charges in the capacitors to avoid a data loss. This refresh operation may be performed globally on the memory array 301, and all memory rows are refreshed row by row, until refresh of all the memory rows is completed. Generally, the global refresh operation in the example is performed after one read/write cycle. A read or write operation is performed on a memory array 301 in the read/write cycle. After the cycle ends, a refresh cycle starts, and after the refresh cycle ends, the read/write cycle starts again, and so on. In this way, a risk of data loss caused by charge leakage of the memory cells 305 is reduced, thereby maintaining good stability of the memory device 104.

In some examples, the row-hammer attack is random, and it is not known which memory row is attacked and which memory row has data errors until bits in the memory row are flipped. Therefore, the frequency of the global refresh operations may be increased to prevent a row-hammer attack, but there will be memory rows that have a high risk and memory rows that have a low risk being refreshed indiscriminately, and there is repetitive refresh. The increase in the frequency of refreshing may take up more than 30% to 40% of the system bandwidth, reducing the bandwidth for reads and writes and reducing the operating performance of the memory device 104. In some examples, performing a refresh operation on memory cells 305 in a memory row may be performed by reading the memory cells 305, determining whether the information stored in the memory cells 305 is correct, and charging the memory cells 305 if the information is incorrect. The charging process may be equivalent to a rewrite process as a means of recovering the data originally stored in the memory cells 305.

In view of this, examples of the present disclosure provide a memory device 104 and a control method thereof, to reduce a risk that a memory row in a row-hammer attack has a data error.

According to some aspects of examples of the present disclosure, with reference to FIG. 3, a memory device is provided. The memory device includes a memory array 301 and a peripheral circuit 302 coupled to the memory array 301. The memory array 301 includes a plurality of memory rows, and each of the memory rows includes a plurality of memory cells 305 coupled to one word line. The peripheral circuit 302 is configured to determine, in response to a read command, whether address information same as first address information of a first memory row 307 corresponding to the read command exists in a refresh table. The refresh table stores a plurality of pieces of address information, and each of the plurality of pieces of address information corresponds to one of the plurality of memory rows; and delete the address information same as the first address information from the refresh table in response to the address information same as the first address information existing in the refresh table.

In some examples, with reference to FIG. 4, the peripheral circuit 302 includes a control logic 304 and a comparison circuit 306 coupled to the control logic. The comparison circuit 306 is configured to, in response to the read command ACT, acquire individual pieces of address information in the refresh table and compare the first address information with the individual pieces of address information one by one to generate a comparison result. The comparison circuit 306 is further configured to send the comparison result to the control logic 304. The control logic 304 is configured to determine, according to the comparison result, whether the address information same as the first address information exists in the refresh table. The control logic 304 is further configured to delete the first address information from the refresh table in response to the address information same as the first address information existing in the refresh table. The read command may be generated by the host 108 or the memory controller 106 and sent to the memory device 104, and the read command may include first address information to be read; or the first address information is generated along with the read command, and is sent to the memory device 104 along with the read command, or the first address information is sent to the memory device 104 after the read command. The control logic 304 may control devices such as the row decoding circuit, the column decoding circuit and the like in response to the read command to perform a read operation on the first memory row 307; and the control logic 304 performs a refresh operation on a corresponding memory row according to address information stored in the refresh table.

With reference to FIG. 3, the memory rows correspond to the word lines in the memory device 104. One memory row may include memory cells 305 coupled to one word line. The first memory row 307 may be a memory row corresponding to any word line in the memory array 301, for example, may be a memory row corresponding to the word line WLn. The first address information may correspond to address information of one memory cell, a plurality of memory cells, or all the memory cells 305 in the first memory row 307.

In some examples, the refresh table is applicable to global refresh of all the memory rows in the memory array 301, and the refresh table here may store address information corresponding to all the memory rows in the memory array 301 as a global refresh table. When the refresh table is the global refresh table, the peripheral circuit 302 may access the refresh table in response to a refresh command, acquire the address information in the refresh table sequentially according to a preset refresh rule, and perform a refresh operation on the memory row. The peripheral circuit 302 may sequentially refresh the memory rows starting from any address information in the refresh table, until refresh of the memory rows corresponding to all the address information in the refresh table is completed. The refresh table in the examples of the present disclosure has a large data amount when being used as the global refresh table, and the global refresh table may be divided into a plurality of sub-refresh tables.

Different from the global refresh table in some examples, the refresh table in some other examples of the present disclosure is applicable to refresh with prevention of a row-hammer attack. The peripheral circuit 302 may be configured to access the refresh table in response to a read command or in response to a write command, acquire the address information stored in the refresh table, and perform a refresh operation on a memory row. If data in the refresh table is bit-flipped, the peripheral circuit 302 may perform an error correction operation on the data to re-write correct data. It may be understood that, a row-hammer attack is random. The first memory row 307 may be an attacked row that suffers a row-hammer attack, and a memory row adjacent to the first memory row is a high-risk victim row and has a huge risk of bit flipping. Alternatively, the first memory row 307 may be a victim row of bit flipping, and it cannot be known before the first memory row 307 is read or refreshed whether the first memory row 307 is bit-flipped. After the first memory row 307 is read, if data of the first memory row 307 is bit-flipped, the peripheral circuit 302 may also perform an error correction operation to restore the data thereof. If the first address information still exists in the refresh table, the peripheral circuit 302 refreshes the first memory row 307 after reading the first memory row 307, and the refresh operation at this time is unnecessary. After the first memory row 307 is read, and the data thereof is not bit-flipped, a memory row adjacent to the first memory row is a high-risk victim row and may be bit-flipped due to interference or charge leakage of the first memory row 307. The address information of the memory row adjacent to the first memory row 307 is stored in the refresh table, or address information corresponding to the memory row adjacent to the first memory row 307 is inserted into the refresh table for retrieval and refresh by the peripheral circuit 302, thereby reducing the risk of a row-hammer attack.

In the examples of the present disclosure, a read operation is performed on the first memory row 307 corresponding to the first address information in response to the read command, whether data stored in the first memory row 307 has an error may be determined by the read operation. The address information same as the first address information that exists in the refresh table is deleted, to avoid repetitive refresh of the first memory row 307, thereby improving the operation efficiency of the memory device 104.

In some examples, the plurality of pieces of address information are sorted by priority. The peripheral circuit 302 is further configured to perform a refresh operation on a corresponding memory row according to address information with the highest priority in the refresh table, and delete the address information with the highest priority from the refresh table after the refresh operation.

In some examples, priority of each of the plurality of pieces of address information is determined according to a probability that the memory row corresponding to the address information suffers a row-hammer attack. When the probability that the memory row suffers a row-hammer attack is higher, the priority level is higher, and the memory row is refreshed earlier. It may be understood that, in the examples of the present disclosure, after the address information with the highest priority in the refresh table is refreshed and deleted, priority of remaining address information is all raised by one level. In this way, address information that was previously has the second highest priority is updated to the highest priority and can be refreshed in a next operation. A new memory row is further introduced into the refresh table and is stored with the lowest priority.

A row-hammer attack is a random event, and an attacked memory row is also random. A probability that a memory row is subject to a row-hammer attack may be recorded based on a history of row-hammer attacks on some memory device 104, and the higher the number of historical attacks, the higher the probability. Alternatively, the probability that a memory row is subject to a row-hammer attack may be determined based on the number of times the memory row has been read, and the higher the number of times the memory row has been read, the higher the probability. Furthermore, in combination with a probabilistic algorithm to assign the probability of each memory row being subjected to a row-hammer attack, the refresh table only stores a certain amount of address information with a high probability of row-hammer attack, and address information of all memory rows is not stored as a way to reduce the volume of data in the refresh table. In addition, when a certain piece of address information in the refresh table is deleted and address information of other memory rows needs to be inserted, the inserted address information is also determined according to the probabilistic algorithm in order to insert the address information with a higher risk, and the address information with a higher risk here is determined in real time by a built-in probabilistic algorithm. The address information stored in the refresh table changes in real time with the refresh operation, which is more secure than the refresh table with fixed address information.

In some examples, the peripheral circuit 302 is further configured to determine whether address information of a memory row adjacent to the first memory row 307 exists in the refresh table; insert the address information of the memory row adjacent to the first memory row 307 into the refresh table in response to the address information of the memory row adjacent to the first memory row 307 not existing in the refresh table. The peripheral circuit 302 is further configured to adjust priority of the address information of the memory row adjacent to the first memory row 307 in the refresh table in response to the address information of the memory row adjacent to the first memory row 307 existing in the refresh table.

Based on the bit-flip model caused by a row-hammer attack, when the first memory row 307 is read, its adjacent memory rows have a high risk of bit-flip, and the peripheral circuit 302 needs to determine whether address information of a memory row adjacent to the first memory row 307 exists in the existing refresh table. If not, the address information of the memory row adjacent to the first memory row 307 is inserted into the refresh table, to avoid the high-risk memory rows being omitted from the refresh. Inserted address information may have a non-highest priority in the refresh table, and address information with the highest priority in the refresh table before insertion has the highest risk. If the address information of the memory row adjacent to the first memory row 307 is recorded in the refresh table, it indicates that a default risk level of the address information is very high, and currently there is a risk of being interfered by the first memory row 307. In this case, priority of the address information in the refresh table needs to be raised.

In some examples, with reference to FIG. 4, the comparison circuit 306 accesses the refresh table and compares the first address information with the address information stored in the refresh table one by one in response to the read command ACT, and sends the comparison result and the addresses in the comparison to the control logic 304. The control logic 304 determines, according to the comparison result, that the first address information exists in the refresh table, and deletes the first address information. The control logic 304 determines, according to the comparison result, that address information of the memory row adjacent to the first memory row 307 does not exist in the refresh table, and inserts the address information of the memory row adjacent to the first memory row 307 into the refresh table. The control logic 304 determines, according to the comparison result, that address information of a memory row adjacent to the first memory row 307 exists in the refresh table, and adjusts priority of the address information of the memory row adjacent to the first memory row 307 in the refresh table. The control logic 304 accesses the refresh table to acquire address information with the highest priority in the refresh table, perform the refresh operation on a memory row corresponding to the address information with the highest priority, refreshes the memory row corresponding to the address information with the highest priority, and deletes the address information with the highest priority from the refresh table after the refresh operation.

In some examples, the memory row adjacent to the first memory row 307 includes a second memory row and/or a third memory row. The peripheral circuit 302 is further configured to determine whether address information same as second address information corresponding to the second memory row exists in the refresh table; and/or determine whether address information same as third address information corresponding to the third memory row exists in the refresh table. The peripheral circuit 302 is further configured to insert the second address information into the refresh table in response to the second address information not existing in the refresh table; and/or, insert the third address information into the refresh table in response to the third address information not existing in the refresh table. The peripheral circuit 302 is further configured to adjust priority of at least one of the second address information or the third address information in the refresh table in response to the second address information and/or the third address information existing in the refresh table.

With reference to FIG. 3, when the first memory row 307 is a memory row at the edge of the memory array 301, for example, a memory row corresponding to the first word line WL0 or the last word line WLn+n, only one memory row is adjacent to the first memory row 307, which may be denoted as the second memory row or the third memory row. The second memory row and the third memory row correspond to the second address information and the third address information respectively. Taking the second memory row as an example, when the second address information does not exist in the refresh table, the second address information is inserted into the refresh table; and when the second address information exists in the refresh table, priority of the second address information in the refresh table is adjusted.

When the first memory row 307 is a memory row between the edges in the memory array 301, for example, a memory row corresponding to a word line WLn, two memory rows are adjacent to the first memory row 307, and are respectively a second memory row and a third memory row. When neither second address information nor third address information is in the refresh table, the two pieces of address information are both inserted into the refresh table. When one of the second address information and the third address information is in the refresh table and the other is not in the refresh table, for example, when the second address information is in the refresh table and the third address information is not in the refresh table, the third address information is inserted into the refresh table, and priority of the second address information in the refresh table is adjusted. When the second address information and the third address information are both in the refresh table, priority of the second address information and the third address information in the refresh table are adjusted, and relative priority of the two pieces of address information may be kept unchanged or switched before and after adjustment. For example, before the refresh table is adjusted, the priority of the second address information is higher than that of the third address information, and the priority of the second address information may still be higher than that of the third address information after adjustment, or the priority of the third address information may be higher than that of the priority of the second address information after adjustment.

In some examples, after one or two pieces of address information are inserted into the refresh table, it is necessary to delete address information of which the number is equal to that of inserted address information, to keep the number of pieces of address information stored in the refresh table in real time unchanged, that is, keep a queue depth corresponding to the refresh table unchanged. The refresh table can go through operations such as address information insertion, deletion, or priority adjustment, and only the address information with the highest priority in the refresh table is refreshed in a single refresh operation.

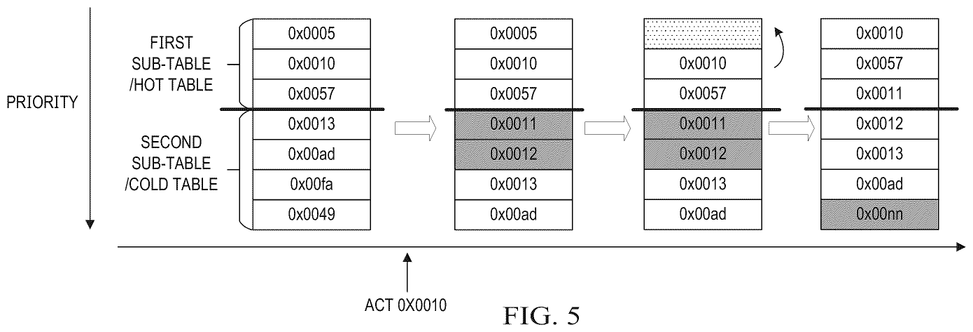

In some examples, with reference to FIG. 5, the refresh table includes a first sub-table and a second sub-table, and priority of address information in the first sub-table is higher than priority of address information in the second sub-table. The first sub-table may be denoted as a hot table, including address information with a higher risk or probability of a row-hammer attack. The second sub-table may be denoted as a cold table, including address information with a lower risk or probability of a row-hammer attack. Address information with the highest priority in the first sub-table is refreshed.

The address information with the highest priority in the first sub-table is address information on which refresh is currently performed. The address information with the highest priority is deleted from the refresh table after being refreshed, priority of other address information is sequentially raised by one level, and one new piece of address information is added and has the lowest priority in the refresh table, to keep the number of pieces of address information stored in the refresh table unchanged. Taking FIG. 5 as an example, the refresh table has seven entries (seven boxes), the first sub-table includes three entries, storing three pieces of address information, and the second sub-table includes four entries, storing four pieces of address information. Priority in the refresh table sequentially decrease with the arrow, address information in an entry with the highest priority is refreshed, the number of entries (or a queue depth) in the refresh table remains unchanged, but the address information corresponding to each entry keeps changing with the insertion of address information as well as the refresh. After the address information in the entry with the highest priority is deleted due to refresh, there may be a temporary vacancy, but is immediately filled in due to adjustment and update of priority for the next refresh. In one refresh operation, only address information with the highest priority in the refresh table is refreshed.

In some examples, the peripheral circuit 302 is further configured to insert the address information of the memory row adjacent to the first memory row 307 into the second sub-table in response to the address information of the memory row adjacent to the first memory row 307 not existing in the refresh table. Priority of the address information of the memory row adjacent to the first memory row 307 is the highest priority in the second sub-table.

In some examples, when the first memory row 307 has only one adjacent memory row, there is only one piece of address information adjacent to the first address information, e.g., the second address information. When the second address information exists in neither the first sub-table nor the second sub-table, the second address information is inserted into the second sub-table and has the highest priority. Address information with the lowest priority in the second sub-table may be deleted or not deleted. In some examples, when the second address information is stored in the first sub-table, the priority of the second address information is raised to the highest priority in the first sub-table. If the second address information previously has the highest priority in the first sub-table, no adjustment is required, the second address information with the highest priority is refreshed, and second address information is deleted from the first sub-table after the refresh operation. In some examples, when the second address information is stored in the second sub-table, the second address information is moved to the first sub-table and has the lowest priority in the first sub-table. In subsequent examples, the operations of inserting address information, deleting address information, and adjusting the priority of the refresh table when the first address information has second address information and third address information that are adjacent will be described.

In some examples, the memory row adjacent to the first memory row 307 includes a second memory row and a third memory row, and the peripheral circuit 302 is further configured to, in response to address information same as the second address information and address information same as the third address information not existing in the refresh table, insert second address information corresponding to the second memory row and third address information corresponding to the third memory row into the second sub-table. Priority of the second address information is the highest priority in the second sub-table, and priority of the third address information is the second highest priority in the second sub-table. Or, priority of the second address information is the second highest priority in the second sub-table, and priority of the third address information is the highest priority in the second sub-table.

In some examples, when the first memory row 307 have two adjacent memory rows. The peripheral circuit 302 is further configured to insert the second address information or the third address information into the second sub-table in response to the second address information or the third address information not existing in the refresh table, to enable the priority of the second address information or the third address information to be the highest priority in the second sub-table. The peripheral circuit 302 is further configured to insert the second address information and the third address information into the second sub-table in response to second address information and third address information not existing in the refresh table. The priority of the second address information to be the highest priority in the second sub-table, and the priority of the third address information to be the second highest priority in the second sub-table. Or, the priority of the second address information to be the second highest priority in the second sub-table, and the priority of the third address information to be the highest priority in the second sub-table.

With reference to FIG. 5, before a response is made to the read command, address information corresponding to a plurality of memory rows stored in the refresh table is 0x0005, 0x0010, 0x0057, 0x0013, 0x00ad, 0x00fa, 0x0049, in decreasing order of priority. The read command ACT 0x0010 corresponds to first address information 0x0010, address information of an adjacent memory row of the first address information 0x0010 includes second address information 0x0011 and third address information 0x0012. The two pieces of address information are in neither the first sub-table nor the second sub-table, therefore 0x0011 is inserted into the second sub-table and has the highest priority in the second sub-table, and 0x0012 is inserted into the second sub-table and has the second highest priority in the second sub-table. Alternatively, 0x0012 is inserted into to the second sub-table and has the highest priority in the second sub-table, and 0x0011 is inserted into the second sub-table and has the second highest priority in the second sub-table. After two pieces of address information are inserted into the second sub-table, the second sub-table has two more pieces of address information are added, and two pieces of address information with the lowest priority and the second lowest priority in the second sub-table may be deleted or not deleted. In FIG. 5, after 0x0011 and 0x0012 are inserted into the second sub-table, 0x00fa and 0x0049 are deleted. The address information 0x0005 with the highest priority in the first sub-table is deleted from the first sub-table after the refresh operation, and the entry with the highest priority in the first sub-table is temporarily vacant. Subsequently, priority of 0x0010, 0x0057, 0x0011, 0x0012, 0x0013, and 0x00ad are sequentially raised by one level. 0x0010 becomes the one with the new highest priority, and fourth address information corresponding to a fourth memory row is inserted into the second sub-table and has the lowest priority. The fourth address information may be obtained according to a probabilistic algorithm, and the fourth address information may include 0x00nn. It needs to be noted that in FIG. 5, before 0x0011 and 0x0012 are inserted, the first address information 0x0010 exists in the refresh table (the first sub-table), and even if being read, the first address information 0x0010 is not deleted from the refresh table.

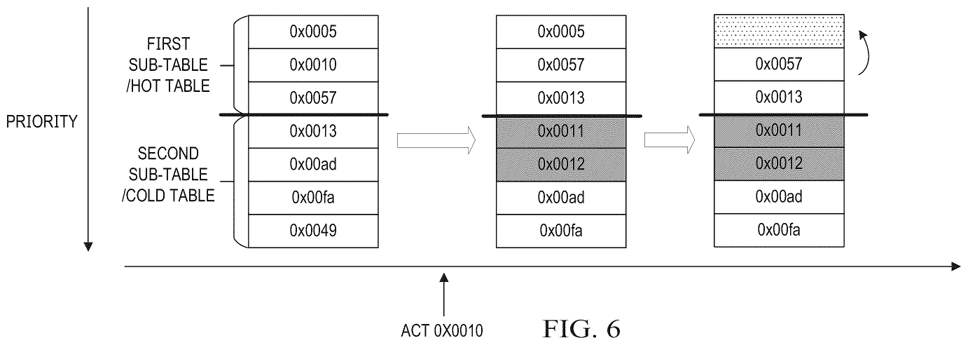

With reference to FIG. 6, in response to reading the first address information 0x0010, the first address information 0x0010 exists in the refresh table, and the first address information 0x0010 is deleted from the refresh table. Similar to FIG. 5, after the second address information 0x0011 and the third address information 0x0012 are inserted into the second sub-table, because the first address information 0x0010 is deleted previously, it is only necessary to delete one piece of address information in the second sub-table, such as 0x0049 with the lowest priority in the second sub-table. Compared with the example shown in FIG. 5, one more piece of high-risk address information 0x00fa is kept, to further reduce the probability of a row-hammer attack.

It needs to be noted that, in some other examples, for the refresh table in which the second address information and the third address information are not inserted, the address information 0x0005, 0x0010, 0x0057, 0x0013, 0x00ad, 0x00fa, and 0x0049 may be sequentially refreshed in decreasing order of priority.

In some examples, the peripheral circuit 302 is further configured to adjust priority of the address information of the memory row adjacent to the first memory row 307 to the highest priority in the first sub-table in response to the address information of the memory row adjacent to the first memory row 307 existing in the first sub-table.

In some examples, the peripheral circuit 302 is further configured to move the address information of the memory row adjacent to the first memory row 307 into the first sub-table in response to the address information of the memory row adjacent to the first memory row 307 existing in the second sub-table. In some examples, priority of the address information of the memory row adjacent to the first memory row 307 is the lowest priority in the first sub-table.

When the first memory row 307 has only one adjacent memory row, there is only one piece of address information adjacent to the first address information, e.g., the second address information. In some examples, when the second address information exists in the first sub-table, priority of the second address information is adjusted to the highest priority in the first sub-table. In some other examples, when the second address information exists in the second sub-table, the second address information is moved to the first sub-table, and priority of the second address information may be adjusted to the lowest priority or the second lowest priority in the first sub-table.

In some examples, the peripheral circuit 302 is further configured to adjust priority of the second address information or the third address information to the highest priority in the first sub-table in response to the second address information or the third address information existing in the first sub-table. In other examples, the peripheral circuit 302 is further configured to adjust priority of the second address information and the third address information to the highest priority and the second highest priority in the first sub-table respectively in response to the second address information and the third address information existing in the first sub-table.

In some examples, the peripheral circuit 302 is further configured to move at least one of the second address information or the third address information into the first sub-table in response to at least one of the second address information or the third address information existing in the second sub-table.

In some examples, the peripheral circuit 302 is further configured to move the second address information or the third address information into the first sub-table in response to the second address information or the third address information existing in the second sub-table, to enable the priority of the second address information or the third address information to be the lowest priority in the first sub-table. In other examples, the peripheral circuit 302 is further configured to move the second address information and the third address information into the first sub-table in response to the second address information and the third address information existing in the second sub-table. The priority of the second address information to be the lowest priority in the first sub-table and the priority of the third address information to be the second lowest priority in the first sub-table. Or, The priority of the second address information to be the second lowest priority in the first sub-table and the priority of the third address information to be the lowest priority in the first sub-table.

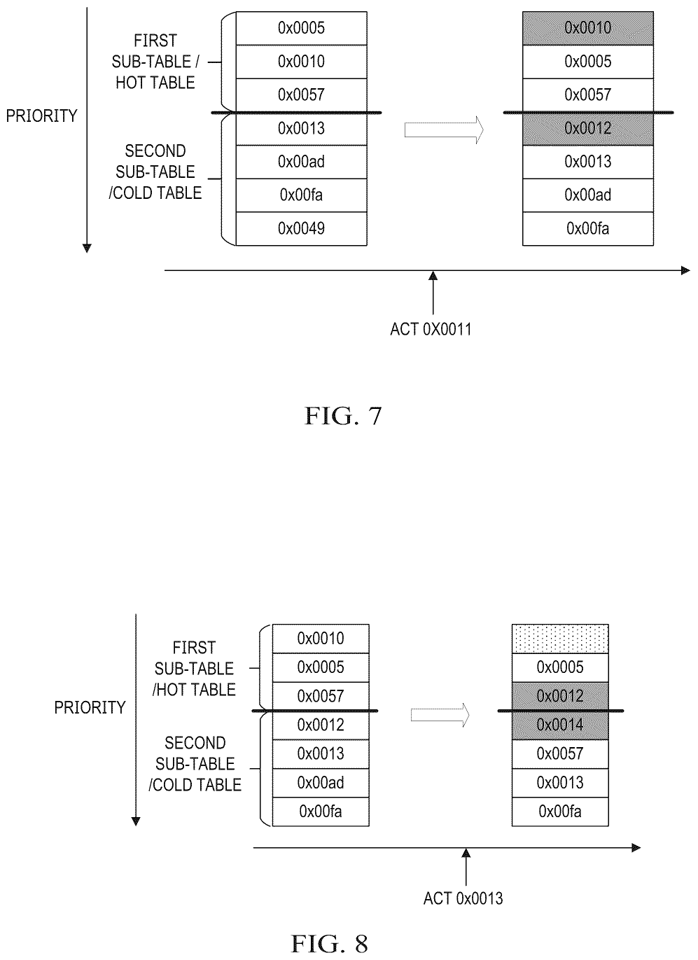

With reference to FIG. 7, before a response is made to the read command, the address information stored in the refresh table is 0x0005, 0x0010, 0x0057, 0x0013, 0x00ad, 0x00fa, and 0x0049. 0x0005, 0x0010. 0x0005, 0x0010, and 0x0057 belong to the first sub-table, and 0x0013, 0x00ad, 0x00fa, and 0x0049 belong to the second sub-table. In response to a read command ACT 0x0011 corresponding to the first address information 0x0011, two adjacent pieces of address information 0x0010 and 0x0012 originally need to be inserted into the second sub-table and have the highest priority and the second highest priority respectively. However, only 0x0010 is stored in the first sub-table, and only priority of 0x0010 is adjusted to the highest priority in the first sub-table. 0x0012 is stored in neither the first sub-table nor the second sub-table, and 0x0012 is inserted into the second sub-table and has the highest priority. The address information 0x0049 with the lowest priority in the second sub-table is deleted. 0x0010 will be refreshed, and deleted from the first sub-table after being refreshed.

With reference to FIG. 8, before a response is made to the read command, the address information stored in the refresh table is 0x0010, 0x0005, 0x0057, 0x0012, 0x0013, 0x00ad, and 0x00fa. 0x0010, 0x0005, and 0x0057 belong to the first sub-table, and 0x0012, 0x0013, 0x00ad, and 0x00fa belong to the second sub-table. In response to a read command ACT 0x0013 corresponding to the first address information 0x0013, two adjacent pieces of address information 0x0012 and 0x0014 originally need to be inserted into the second sub-table and have the highest priority and the second highest priority respectively. However, only 0x0012 is stored in the second sub-table, and 0x0012 is moved into the first sub-table and has the lowest priority. 0x0014 is stored in neither the first sub-table nor the second sub-table, and 0x0014 is inserted into the second sub-table and has the highest priority. After an adjustment operation, the address information with the highest priority in the first sub-table is still 0x0010, and 0x0010 will be refreshed, and deleted from the first sub-table after being refreshed. One piece of address information 0x00ad in the second sub-table is deleted, and 0x00ad does not have the lowest priority in the second sub-table. The first address information 0x0013 is stored in the second sub-table, and is not deleted from the refresh table after being read.

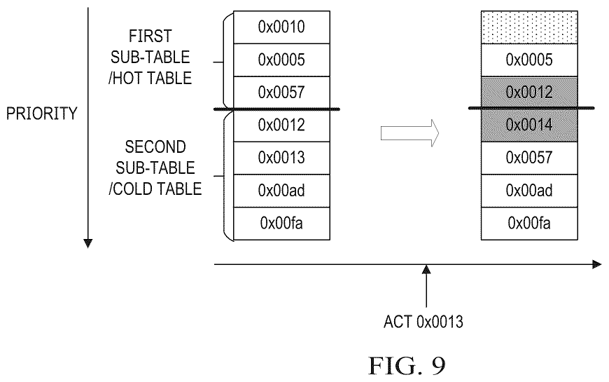

With reference to FIG. 9, before a response is made to the read command, the address information stored in the refresh table is 0x0010, 0x0005, 0x0057, 0x0012, 0x0013, 0x00ad, and 0x00fa. 0x0010, 0x0005, and 0x0057 belong to the first sub-table, and 0x0012, 0x0013, 0x00ad, and 0x00fa belong to the second sub-table. In response to the read command ACT 0x0013 corresponding to the first address information 0x0013, 0x0012 in the second sub-table is moved into the first sub-table and has the lowest priority, 0x0014 is inserted into the second sub-table and has the highest priority, and 0x0013 of the second sub-table is deleted. After an adjustment operation, the address information with the highest priority in the first sub-table is still 0x0010, and 0x0010 will be refreshed, and deleted from the first sub-table after being refreshed. Compared with FIG. 8, in FIG. 9, because the first address information 0x0013 is deleted, while the number of pieces of address information in the refresh table is kept unchanged, one fewer piece of address information may be deleted from the second sub-table, that is, one more piece of high risk address information is kept, to reduce a risk of a row-hammer attack. For example, 0x00ad is kept in FIG. 9.

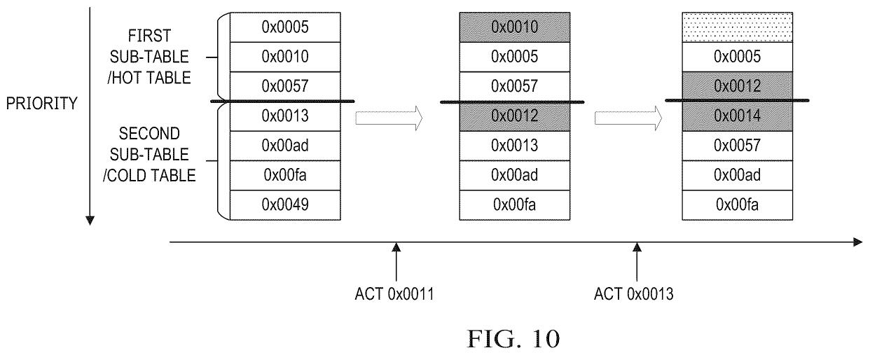

In some examples, operation timing of a DRAM may include a read/write cycle and a refresh cycle. In one read/write cycle, the memory device 104 may receive a plurality of read commands. In response to each read command, the peripheral circuit 302 performs operations of inserting address information, adjusting priority or deleting address information and the like on the refresh table according to read address information to update the refresh table in real time, but is not limited to performing one refresh operation in response to each read command. For example, as shown in FIG. 10, the read commands ACT 0x0011 and ACT 0x0013 are sequentially received. Before a response is made to the first read command, the address information stored in the refresh table is 0x0005, 0x0010, 0x0057, 0x0013, 0x00ad, 0x00fa, and 0x0049. 0x0005, 0x0010, and 0x0057 belong to the first sub-table, and 0x0013, 0x00ad, 0x00fa, and 0x0049 belong to the second sub-table. In response to the read command ACT 0x0011, 0x0010 is stored in the first sub-table, and 0x0010 is moved into the first sub-table and has the highest priority. 0x0012 is stored in neither the first sub-table nor the second sub-table, and 0x0012 is inserted into the second sub-table and has the highest priority. The address information 0x0049 with the lowest priority in the second sub-table is deleted, and 0x0010 with the highest priority is not refreshed. In response to the read command ACT 0x0013, 0x0012 is stored in the second sub-table, and 0x0012 is moved into the first sub-table and has the lowest priority. 0x0014 is stored in neither the first sub-table nor the second sub-table, and 0x0014 is inserted into the second sub-table and has the highest priority. 0x0013 stored in the second sub-table is read and then deleted from the second sub-table, and 0x0010 with the highest priority is refreshed and is deleted from the first sub-table.

In some examples, with reference to FIG. 10, the refresh table may be used for an additional refresh operation other than a global refresh operation (or an automatic refresh operation) in the memory device 104. 0x0010 with the highest priority in the refresh table may be additionally refreshed once on the basis of the global refresh operation, the additional refresh operation may be performed in the refresh cycle, and 0x0010 may be refreshed twice in the refresh cycle. When the refresh cycle is after the timing of the read command ACT 0x0013, the peripheral circuit 302 performs a refresh operation in the refresh cycle according to a current latest refresh table, and refresh a memory row corresponding to 0x0010 with the highest priority. The read command ACT 0x0011 in the timing of the read/write cycle triggers update of the refresh table, but a refresh operation is not performed. That is, currently, a memory row corresponding to 0x0010 with the highest priority is not refreshed.

In some examples, the peripheral circuit 302 is further configured to delete at least one piece of address information in the second sub-table when the number of pieces of address information stored in the second sub-table is greater than a set threshold. For the second sub-table, one piece of address information adjacent to the first memory row 307 may be inserted, or two pieces of address information adjacent to the first memory row 307 may be inserted. When the number of pieces of address information stored in the second sub-table is greater than a set storage number of the second sub-table, address information with a lower priority in the second sub-table may be deleted, and address information with a lower priority is to be deleted earlier.

In some examples, the peripheral circuit 302 is further configured to, in response to at least one of the second address information or the third address information being inserted into the second sub-table so that the number of pieces of address information stored in the second sub-table to be greater than a set threshold, delete at least one piece of address information in the second sub-table.

In some examples, the peripheral circuit 302 is configured to delete address information in the second sub-table in order of priority. Address information with a lower priority is to be deleted earlier.

The number of pieces of address information stored in the refresh table in the examples of the present disclosure is a fixed value, and the number of pieces of address information stored in the first sub-table and that in the second sub-table are fixed values. In response to a read command corresponding to different address information, content and priority of address information in the refresh table are updated in real time. However, the number of pieces of address information in the refresh table is kept unchanged, to keep a small data amount of the refresh table. For example, as shown in FIG. 5, the second address information 0x0011 and the third address information 0x0012 are inserted into the second sub-table, thus the number of pieces of address information in the second sub-table is larger than the set threshold of 4 by 2. 0x0049 with the lowest priority and 0x00fa with the second lowest priority in the second sub-table are deleted, to keep the set threshold of 4 of the second sub-table. In another example, as shown in FIG. 7, one piece of address information 0x0012 is inserted into the second sub-table, and 0x0049 with the lowest priority is deleted.

When address information is deleted from the second sub-table, address information with the lowest priority may be deleted in order of priority, or may be randomly deleted. However, newly inserted address information is not deleted. For example, as shown in FIG. 8, address information 0x0014 is inserted into the second sub-table, and 0x00ad with a non-lowest priority is deleted. In this way, the security of a refresh table update algorithm can be increased, thereby improving the performance of dealing with a row-hammer attack of the memory device 104, and improving the security performance of the memory device 104.

In some examples, the peripheral circuit 302 is further configured to raise all priority corresponding to remaining address information in the refresh table by one level in response to the address information with the highest priority being deleted from the refresh table after the refresh operation. In some examples, the peripheral circuit 302 is further configured to insert fourth address information corresponding to a fourth memory row into the refresh table. Priority of the fourth address information is the lowest priority in the refresh table.

With reference to FIG. 5, 0x0005 with the highest priority is deleted from the refresh table after being refreshed. An entry with the highest priority in the refresh table is temporarily vacant. Subsequently, priority of 0x0010, 0x0057, 0x0011, 0x0012, 0x0013, and 0x00ad are sequentially raised by one level. 0x0010 becomes the one with the new highest priority, and fourth address information corresponding to a fourth memory row is inserted into the second sub-table and has the lowest priority. The fourth address information may be obtained according to a probabilistic algorithm, and the fourth address information may include 0x00nn.

In some other examples, after 0x0005 is refreshed and deleted, priority of current remaining 0x0010 and 0x0057 in the first sub-table may be sequentially raised by one level, thus 0x0010 has the highest priority, the lowest priority is vacant, and the fourth address information is inserted into the first sub-table and has the lowest priority.

According to some aspects of examples of the present disclosure, FIG. 1 provides a memory system, including a memory device 104 and a memory controller 106. The memory controller 106 is coupled to the memory and configured to control the memory device 104. The memory device 104 may include a DRAM. The memory device 104 includes a DRAM, or a package structure formed by stacking a plurality of DRAMs, for example, an HBM or HMC package structure. The memory device 104 may include, but is not limited to, a double data rate synchronous dynamic random access memory using DDR4 memory specifications and DDR5 memory specifications and a low-power consumption double data rate synchronous dynamic random access memory using LPDDR5 memory specifications.

In some examples, with reference to FIG. 2, a controller that controls the memory device 104 may be located inside the host 108, for example, a memory controller may be integrated in a central processing unit (CPU), or a southbridge or northbridge chip may be integrated in a mainboard of the system 100.

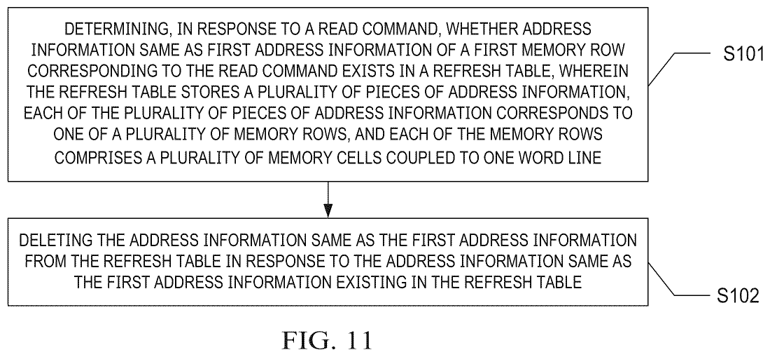

According to some aspects of examples of the present disclosure, FIG. 11 provides a method of controlling a memory device. At S101, the method may include determining, in response to a read command, whether address information same as first address information of a first memory row corresponding to the read command exists in a refresh table. The refresh table stores a plurality of pieces of address information each corresponding to one of a plurality of memory rows. In some examples, Each of the plurality of memory rows includes a plurality of memory cells coupled to one word line. At S102, the method further includes deleting the address information same as the first address information from the refresh table in response to the address information same as the first address information existing in the refresh table.

In some examples, the plurality of pieces of address information are sorted by priority, and the method further includes performing a refresh operation on a corresponding memory row according to address information with the highest priority in the refresh table, and deleting the address information with the highest priority from the refresh table after the refresh operation.

In some examples, the method includes determining whether address information of a memory row adjacent to the first memory row 307 exists in the refresh table. In some examples, the method further includes inserting the address information of the memory row adjacent to the first memory row 307 into the refresh table in response to the address information of the memory row adjacent to the first memory row 307 not existing in the refresh table. In some examples, the method further includes adjusting priority of the address information of the memory row adjacent to the first memory row 307 in the refresh table in response to the address information of the memory row adjacent to the first memory row 307 existing in the refresh table.

In some examples, The memory row adjacent to the first memory row 307 includes at least one of the second memory row or the third memory row. The method includes determining whether address information same as second address information corresponding to a second memory row exists in the refresh table; and/or determining whether address information same as third address information corresponding to a third memory row exists in the refresh table. In some examples, the method further includes inserting the second address information into the refresh table in response to the second address information not existing in the refresh table. In some examples, the method further includes inserting the third address information into the refresh table in response to the third address information not existing in the refresh table. In some examples, the method further includes adjusting priority of at least one of the second address information or the third address information in the refresh table in response to at least one of the second address information or the third address information existing in the refresh table.

In some examples, the refresh table includes a first sub-table and a second sub-table, and priority of address information in the first sub-table is higher than priority of address information in the second sub-table.

In some examples, the method further includes inserting the address information of the memory row adjacent to the first memory row 307 into the second sub-table in response to the address information of the memory row adjacent to the first memory row 307 not existing in the refresh table. Priority of the address information of the memory row adjacent to the first memory row 307 is the highest priority in the second sub-table.

In some examples, the memory row adjacent to the first memory row 307 includes a second memory row and a third memory row. The method includes inserting second address information corresponding to the second memory row and third address information corresponding to the third memory row into the second sub-table in response to address information same as the second address information and address information same as the third address information not existing in the refresh table. In some examples, priority of the second address information is the highest priority in the second sub-table, and priority of the third address information is the second highest priority in the second sub-table. In some examples, priority of the second address information is the second highest priority in the second sub-table, and priority of the third address information is the highest priority in the second sub-table.

In some examples, the method includes adjusting priority of the address information of the memory row adjacent to the first memory row 307 to the highest priority in the first sub-table in response to the address information of the memory row adjacent to the first memory row 307 existing in the first sub-table.

In some examples, the method includes moving the address information of the memory row adjacent to the first memory row 307 into the first sub-table in response to the address information of the memory row adjacent to the first memory row 307 existing in the second sub-table.

In some examples, priority of the address information of the memory row adjacent to the first memory row 307 is the lowest priority in the first sub-table.

In some examples, the method includes inserting the second address information or the third address information into the second sub-table in response to the second address information or the third address information not existing in the refresh table, to enable the priority of the second address information or the third address information to be the highest priority in the second sub-table.

In some examples, the method further includes inserting the second address information and the third address information into the second sub-table in response to second address information and third address information not existing in the refresh table. In some examples, the priority of the second address information to be the highest priority in the second sub-table, and the priority of the third address information to be the second highest priority in the second sub-table. In other examples, the priority of the second address information to be the second highest priority in the second sub-table, and the priority of the third address information to be the highest priority in the second sub-table.

In some examples, the method includes adjusting priority of the second address information or the third address information to the highest priority in the first sub-table in response to the second address information or the third address information existing in the first sub-table. In some examples, the method includes adjusting priority of the second address information and the third address information to the highest priority and the second highest priority in the first sub-table respectively in response to the second address information and the third address information existing in the first sub-table.

In some examples, the method includes moving at least one of the second address information or the third address information into the first sub-table in response to at least one of the second address information or the third address information existing in the second sub-table.

In some examples, the method includes moving the second address information or the third address information into the first sub-table in response to the second address information or the third address information existing in the second sub-table, to enable the priority of the second address information or the third address information to be the lowest priority in the first sub-table.

In some examples, the method includes moving the second address information and the third address information into the first sub-table in response to the second address information and the third address information existing in the second sub-table. In some examples, the priority of the second address information to be the lowest priority in the first sub-table and the priority of the third address information to be the second lowest priority in the first sub-table. In some examples, the priority of the second address information to be the second lowest priority in the first sub-table and the priority of the third address information to be the lowest priority in the first sub-table.

In some examples, the method further includes when the number of pieces of address information stored in the second sub-table is greater than a set threshold, deleting at least one piece of address information in the second sub-table.

In some examples, the method further includes, in response to at least one of the second address information or the third address information being inserted into the second sub-table so that the number of pieces of address information stored in the second sub-table to be greater than a set threshold, deleting at least one piece of address information in the second sub-table.

In some examples, the method includes deleting address information in the second sub-table in order of priority. Address information with a lower priority is to be deleted earlier.

In some examples, the method includes raising all priority corresponding to remaining address information in the refresh table by one level in response to the address information with the highest priority being deleted from the refresh table after the refresh operation; and inserting fourth address information corresponding to a fourth memory row into the refresh table. Priority of the fourth address information is the lowest priority in the refresh table.

In some examples, priority of each piece of address information of the plurality of pieces of address information is determined according to a probability that a memory row corresponding to the address information suffers a row-hammer attack.

The above descriptions are merely specific implementations of the present disclosure, and the protection scope of the present disclosure is not limited thereto. Any variation or alternatives that may be readily contemplated by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory device, comprising:
a memory array comprising memory rows, wherein each of the memory rows comprises memory cells coupled to one word line; and
a peripheral circuit coupled to the memory array and configured to:
determine, in response to a read command, whether address information same as first address information of a first memory row corresponding to the read command exists in a refresh table, wherein the refresh table stores pieces of address information, and each piece of the address information corresponds to one of the memory rows; and
delete the address information same as the first address information from the refresh table in response to the address information same as the first address information existing in the refresh table.

2. The memory device of claim 1, wherein the pieces of address information are sorted by priority, and the peripheral circuit is further configured to:
perform a refresh operation on a corresponding memory row according to address information with a highest priority in the refresh table, and
delete the address information with the highest priority from the refresh table after the refresh operation.

3. The memory device of claim 1, wherein the peripheral circuit is further configured to:
determine whether address information of a memory row adjacent to the first memory row exists in the refresh table;
insert the address information of the memory row adjacent to the first memory row into the refresh table in response to the address information of the memory row adjacent to the first memory row not existing in the refresh table; and
adjust priority of the address information of the memory row adjacent to the first memory row in the refresh table in response to the address information of the memory row adjacent to the first memory row existing in the refresh table.

4. The memory device of claim 3, wherein the refresh table comprises a first sub-table and a second sub-table, and priority of address information in the first sub-table is higher than priority of address information in the second sub-table.

5. The memory device of claim 4, wherein the peripheral circuit is further configured to:
insert the address information of the memory row adjacent to the first memory row into the second sub-table in response to the address information of the memory row adjacent to the first memory row not existing in the refresh table, wherein priority of the address information of the memory row adjacent to the first memory row is a highest priority in the second sub-table.

6. The memory device of claim 5, wherein the memory row adjacent to the first memory row comprises a second memory row and a third memory row, and the peripheral circuit is further configured to:
insert second address information corresponding to the second memory row and third address information corresponding to the third memory row into the second sub-table in response to address information same as the second address information and address information same as the third address information not existing in the refresh table,
wherein priority of the second address information is the highest priority in the second sub-table, and priority of the third address information is a second highest priority in the second sub-table; or
priority of the second address information is the second highest priority in the second sub-table, and priority of the third address information is the highest priority in the second sub-table.

7. The memory device of claim 4, wherein the peripheral circuit is further configured to:
adjust priority of the address information of the memory row adjacent to the first memory row to a highest priority in the first sub-table in response to the address information of the memory row adjacent to the first memory row existing in the first sub-table.

8. The memory device of claim 4, wherein the peripheral circuit is further configured to:
move the address information of the memory row adjacent to the first memory row into the first sub-table in response to the address information of the memory row adjacent to the first memory row existing in the second sub-table.

9. The memory device of claim 8, wherein priority of the address information of the memory row adjacent to the first memory row is a lowest priority in the first sub-table.

10. The memory device of claim 5, wherein the peripheral circuit is further configured to:
when a number of pieces of address information stored in the second sub-table is greater than a set threshold, delete at least one piece of address information in the second sub-table.

11. The memory device of claim 10, wherein the peripheral circuit is configured to:
delete address information in the second sub-table in order of priority, wherein address information with a lower priority is to be deleted earlier.

12. The memory device of claim 1, wherein the peripheral circuit comprises:
a control logic; and
a comparison circuit coupled to the control logic and configured to:
acquire, in response to the read command, individual pieces of address information in the refresh table, and compare the first address information with the individual pieces of address information one by one to generate a comparison result; and
send the comparison result to the control logic; and
the control logic is configured to:
determine, according to the comparison result, whether the address information same as the first address information exists in the refresh table; and
delete the first address information from the refresh table in response to the address information same as the first address information existing in the refresh table.

13. A memory system, comprising:
a memory device, comprising:
a memory array comprising memory rows, wherein each of the memory rows comprises memory cells coupled to one word line; and
a peripheral circuit coupled to the memory array and configured to:
determine, in response to a read command, whether address information same as first address information of a first memory row corresponding to the read command exists in a refresh table, wherein the refresh table stores pieces of address information, and each piece of the address information corresponds to one of the memory rows; and
delete the address information same as the first address information from the refresh table in response to the address information same as the first address information existing in the refresh table;
a memory controller coupled to the memory device and configured to control the memory device.

14. A method of controlling a memory device, comprising:
determining, in response to a read command, whether address information same as first address information of a first memory row corresponding to the read command exists in a refresh table, wherein the refresh table stores pieces of address information, each piece of the address information corresponds to one of memory rows, and each of the memory rows comprises memory cells coupled to one word line; and
deleting the address information same as the first address information from the refresh table in response to the address information same as the first address information existing in the refresh table.

15. The method of claim 14, wherein the pieces of address information are sorted by priority, and the method further comprises:
performing a refresh operation on a corresponding memory row according to address information with a highest priority in the refresh table, and deleting the address information with the highest priority from the refresh table after the refresh operation.

16. The method of claim 14, further comprising:
determining whether address information of a memory row adjacent to the first memory row exists in the refresh table;
inserting the address information of the memory row adjacent to the first memory row into the refresh table in response to the address information of the memory row adjacent to the first memory row not existing in the refresh table; and
adjusting priority of the address information of the memory row adjacent to the first memory row in the refresh table in response to the address information of the memory row adjacent to the first memory row existing in the refresh table.

17. The method of claim 16, wherein the refresh table comprises a first sub-table and a second sub-table, and priority of address information in the first sub-table is higher than priority of address information in the second sub-table.

18. The method of claim 17, further comprising:
inserting the address information of the memory row adjacent to the first memory row into the second sub-table in response to the address information of the memory row adjacent to the first memory row not existing in the refresh table, wherein priority of the address information of the memory row adjacent to the first memory row is a highest priority in the second sub-table.

19. The method of claim 18, wherein the memory row adjacent to the first memory row comprises a second memory row and a third memory row, and the method comprises:
inserting second address information corresponding to the second memory row and third address information corresponding to the third memory row into the second sub-table in response to address information same as the second address information and address information same as the third address information not existing in the refresh table,
wherein priority of the second address information is the highest priority in the second sub-table, and priority of the third address information is a second highest priority in the second sub-table; or
priority of the second address information is the second highest priority in the second sub-table, and priority of the third address information is the highest priority in the second sub-table.

20. The method of claim 17, further comprising:
adjusting priority of the address information of the memory row adjacent to the first memory row to a highest priority in the first sub-table in response to the address information of the memory row adjacent to the first memory row existing in the first sub-table.
